(19) United States
(12) Patent Application Publication
(10) Pub. No.: US 2010/0285642 A1
(43) Pub. Date: Nov. 11, 2010

(54) Method of Doping Impurity Ions in Dual Gate and Method of Fabricating the Dual Gate using the same

(75) Inventors: Kyoung Bong Rouh, Icheon-si (KR); Yun Hyuck Ji, Icheon-si (KR); Tae Kyun Kim, Seongnam-si (KR); Woo Sung Kim, Seoul (KR); Seung Mi Lee, Icheon-si (KR)

Correspondence Address: MARSHALL, GERSTEIN & BORUN LLP, 233 SOUTH WACKER DRIVE, 6300 WILLIS TOWER, CHICAGO, IL, 60606-6357, US

(73) Assignee: HYNIX SEMICONDUCTOR INC., Icheon-si (KR)

(21) Appl. No.: 12/558,215

(22) Filed: Sep. 11, 2009

(30) Foreign Application Priority Data
May 8, 2009 (KR) 10-2009-0039989

(51) Int. Cl. H01L 21/8238

(52) U.S. Cl. 438/232; 438/233; 257/E21.635

(57) ABSTRACT

A method of doping impurity ions in a dual gate includes doping first conductivity type impurity ions in a gate conductive layer over a semiconductor substrate having a first region and a second region, wherein the doping is performed with a concentration gradient so that a doping concentration in an upper portion of the gate conductive layer is higher than that in a lower portion; doping second conductivity type impurity ions in a portion of the gate conductive layer in the second region using a mask for opening the portion of the gate conductive layer in the second region; and diffusing the first conductivity type impurity ions and the second conductivity type impurity ions by performing heat treatment.

### CROSS-REFERENCE TO RELATED APPLICATION

Priority to Korean patent application number 10-2009-0039989 filed on May 8, 2009, the entire disclosure of which is incorporated by reference, is claimed.

### BACKGROUND OF THE INVENTION

The invention relates generally to a method of fabricating a semiconductor device and, more particularly, to a method of doping impurity ions in a dual gate and method of fabricating the dual gate using the same.

As the degree of integration of semiconductor devices has increased, application of a Complementary Metal Oxide Semiconductor (CMOS) transistor in which a P-type MOS transistor and an N-type MOS transistor are disposed on the same substrate has gradually grown. In a general CMOS transistor, the P-type MOS transistor has a buried channel structure. In the buried channel structure, a channel length decreases as the degree of integration of a device increases and the influence of an applied electric field increases as the channel length decreases, and leakage current characteristics consequently deteriorate. Accordingly, a dual gate structure is employed to realize a P-type MOS transistor of a surface channel structure. “Dual gate structure” denotes a structure wherein a P-type gate implanted with P-type impurity ions, e.g., boron (B), is disposed in a region formed with the P-type MOS transistor and an N-type gate implanted with N-type impurity ions, e.g., phosphorus (P), is disposed in a region formed with the N-type MOS transistor.

A conventional method of forming the dual gate structure is as follows. First, a gate insulation layer is formed on a semiconductor substrate and a polysilicon layer is formed thereon as a gate conductive layer. N-type impurity ions are doped when forming the polysilicon layer. A doping concentration of the N-type impurity ions is typically about 100% of the final doping concentration. (Herein, “final doping concentration” means a doping concentration sufficient to operate as a gate of an N-type MOS transistor, i.e. an N-type gate.) Next, an ion implantation process using a photoresist layer pattern as mask, which exposes the P-type MOS transistor region, is used to implant the P-type impurity ions in a polysilicon layer of the P-type MOS transistor region. By this ion implantation, a conductivity type of the P-type MOS transistor region is converted from an N-type to a P-type. However, in this case, an effect of the conductivity type conversion in the P-type MOS transistor region tends not to be made to a desired degree since the doping concentration of the N-type impurity ions doped when the polysilicon layer is formed it typically excessively high. Particularly, this phenomenon is more severe, when forming the polysilicon layer with doping the N-type impurity ions, in the case of doping the N-type impurity ions in the lower portion of the polysilicon layer with a relatively higher concentration to prevent movement of a seam that can be generated in the lower portion of the polysilicon layer. As the doping concentration of the N-type impurity ions in the lower portion of the polysilicon layer increases, the degree of conductivity conversion in the lower portion of the polysilicon layer corresponding to the P-type MOS transistor region is low and this results in deterioration of a Poly Depletion Rate (PDR) of the P-type MOS transistor region to exhibit an effect as same as the increase in a thickness of a gate oxide layer.

Accordingly, to solve the above problem, there is a method of implanting the N-type impurity ions doped when forming the polysilicon with a doping concentration other than 100% of the final doping concentration, at a predetermined level, e.g. about 50% of the final doping concentration. Next, a portion of the polysilicon layer corresponding to the P-type MOS transistor region is opened using a first mask and the P-type impurity ions are implanted thereto. Since the doping concentration of the N-type impurity ions within the polysilicon layer is about 50% of the final doping concentration, the degree of conductivity conversion from the N-type to the P-type is sufficient. However, the doping concentration of the N-type impurity ions in the N-type gate is lower than the doping concentration required for the operation as the N-type gate and, in this case, it is necessary to perform an additional ion implantation for opening a portion of the polysilicon layer corresponding to the N-type MOS transistor region using an additional, second mask and implanting the N-type impurity ions with a concentration of the remaining 50%.

FIG. 1 is a graph showing comparison of concentration before and after performing the additional ion implantation of the N-type impurity ions. In FIG. 1, a line designated by a reference numeral 110 indicates the case wherein the additional ion implantation is not performed and a line designated by a reference numeral 120 indicates the case wherein the additional ion implantation is performed. As shown, in the case of implanting phosphorus (P) with a doping concentration of 50% and diffusing the phosphorus (P) by performing a heat treatment upon formation of the polysilicon layer, the concentration of the phosphorus (P) is shown to be lower than the proper concentration indicated by a dotted line A or the concentration allowing the normal operation as the N-type polygate (refer to 110). Accordingly, performance of an additional ion implantation is required, and the concentration of the phosphorus (P) is shown to be higher than the proper concentration indicated by the dotted line A when performing the an additional ion implantation, i.e. in the case of selectively opening only the portion of the polysilicon layer corresponding to the N-type MOS transistor region and additionally ion-implanting the additional N-type impurity ions, e.g. phosphorus (P) with the concentration of rest 50% (refer to 120).

According to this method, the conductivity conversion from the N-type to the P-type in the portion of the polysilicon layer corresponding to the P-type MOS transistor region can be made, and thus the deterioration of the PDR in the P-type MOS transistor region is inhibited. Also, it is possible to maintain the doping concentration of the N-type impurity ions in the portion of the polysilicon layer corresponding to the N-type MOS transistor region at a sufficient level through the additional ion implantation. However, in an aspect of a process, the second mask for opening the portion of the polysilicon layer corresponding to the N-type MOS transistor for the additional ion implantation is required in addition to the first mask for opening the portion of the polysilicon layer corresponding to the P-type MOS transistor and this consequently increases the total cost of the product.

### SUMMARY OF THE INVENTION

Embodiments of the invention are directed to a method of doping impurity ions in a dual gate, capable of preventing deterioration of a Poly Depletion Rate (PDR) in N-type and P-type MOS transistor regions without additionally required mask.

Also, embodiments of the invention are directed to a method of forming a dual gate using the aforementioned impurity implantation method.

In one embodiment, method of doping impurity ions in a dual gate, comprises doping first conductivity type impurity ions in a gate conductive layer over first and second regions of a semiconductor substrate, the gate conductive layer comprising an upper portion overlying a lower portion, wherein the doping is performed with a concentration gradient so that a doping concentration in the upper portion of the gate conductive layer is higher than the doping concentration in the lower portion; doping second conductivity type impurity ions in the gate conductive layer in the second region of the semiconductor substrate using a mask for opening the gate conductive layer in the second region; and diffusing the first conductivity type impurity ions and the second conductivity type impurity ions by performing heat treatment.

The method may further include, after doping the first conductivity type impurity ions, forming an undoped polysilicon layer on the gate conductive layer.

Preferably, the first conductivity type impurity ions are doped with a concentration of 100% of a final doping concentration.

Preferably, a doping concentration of the first conductivity type impurity ions in the lower portion of the gate conductive layer is 20% to 60% of a final doping concentration, and a doping concentration of the first conductivity type impurity ions in the upper portion of the gate conductive layer is 140% to 180% of a final doping concentration.

Preferably, a thickness of the lower portion of the gate conductive layer is 60% to 95% of a total thickness of the gate conductive layer and a thickness of the upper portion of the gate conductive layer is 5% to 40% of the total thickness of the gate conductive layer.

Preferably, the first region is an N-type MOS transistor region and the second region is a P-type MOS transistor region. In this case, the first conductivity type impurity ions are N-type impurity ions and the second conductivity type impurity ions are P-type impurity ions.

Preferably, the gate conductive layer is formed by deposition, and doping the first conductivity type impurity ions in the gate conductive layer is implemented by supplying a source gas of the first conductivity type impurity ions upon deposition of the gate conductive layer. In this case, the doping with the concentration gradient in which the doping concentration in the upper portion of the gate conductive layer is higher than that in the lower portion is implemented by variably controlling an amount of the supplied source gas of the first conductivity type impurity ions.

Preferably, the doping concentration of the impurity ions in the lower portion of the gate conductive layer is 1×10²⁰ to 5×10²⁰ atoms/cm³, and the doping concentration of the impurity ions in the upper portion of the gate conductive layer is larger than the doping concentration of the impurity ions in the lower portion of the gate conductive layer within a range of 1×10²⁰ to 1×10²¹ atoms/cm³.

Preferably, the doping the second conductivity type impurity ions is implemented using a plasma doping method.

Preferably, the heat treatment is implemented using a rapid thermal process.

Preferably, the heat treatment is implemented under an oxygen atmosphere. In this case, a concentration of the oxygen in the oxygen atmosphere preferably is less than 3000 ppm.

Alternatively, the heat treatment may be implemented under an ammonia (NH₃) atmosphere. In this case, a concentration of the ammonia in the ammonia atmosphere preferably is less than 3000 ppm.

In another embodiment, a method of doping impurity ions in a dual gate comprises doping first conductivity type impurity ions in at least three portions of a gate conductive layer over first and second regions of a semiconductor substrate, the at least three portions being divided in a vertical direction of the gate conductive layer, wherein the doping is performed with a concentration gradient so that a doping concentration in the uppermost portion of the gate conductive layer is higher than that in the lowermost portion of the gate conductive layer; doping second conductivity type impurity ions in the gate conductive layer in the second region of the semiconductor substrate using a mask for opening the gate conductive layer in the second region; and diffusing the first conductivity type impurity ions and the second conductivity type impurity ions by performing heat treatment.

The method may further include, after doping the first conductivity type impurity ions, forming an undoped polysilicon layer on the gate conductive layer.

Preferably, the first conductivity type impurity ions are doped with a concentration of 100% of a final doping concentration.

Preferably, the doping the first conductivity type impurity ions in the gate conductive layer is implemented by supplying a source gas of the first conductivity type impurity ions upon deposition of the gate conductive layer. In this case, the doping with the concentration gradient in which the doping concentration in the uppermost portion of the gate conductive layer is higher than that in the lowermost portion is implemented by variably controlling an amount of the supplied source gas of the first conductivity type impurity ions.

Preferably, the gate conductive layer is divided into three portions of a lower portion, a middle portion, and an upper portion in a vertical direction. In this case, a thickness of the lower portion is 10% to 30% of a total thickness of the gate conductive layer, a thickness of the middle portion is 40% to 85% of a total thickness of the gate conductive layer and a thickness of the upper portion of the gate conductive layer is 5% to 30% of the total thickness of the gate conductive layer.

Preferably, a doping concentration of an N-type impurity ions in the lower portion is 10% to 30% of a final doping concentration, a doping concentration of the N-type impurity ions in the middle lower portion is 10% to 30% of a final doping concentration and yet smaller than the doping concentration of the N-type impurity ions in the lower portion, and a doping concentration of the N-type impurity ions impurity ions in the upper portion of the gate conductive layer is 140% to 180% of a final doping concentration.

Preferably, a doping concentration of the impurity ions in the lower portion is 1×10²⁰ to 5×10²⁰ atoms/cm³, a doping concentration of the impurity ions in the middle portion of the gate conductive layer is smaller than the doping concentration of the impurity ions in the lower portion within a range of 1×10²⁰ to 1×10²¹ atoms/cm³, and a doping concentration of the impurity ions in the upper portion is larger than doping concentration of the impurity ions in the lower portion within a range of 1×10²⁰ to 1×10²¹ atoms/cm³.

Preferably, the doping the first conductivity type impurity ions is implemented so that the gate conductive layer is divided into four portions in a vertical direction, a doping concentration of the impurity ions in a first gate portion in a lowermost portion is 1×10²⁰ to 5×10²⁰ atoms/cm³, a doping concentration of the impurity ions in a second gate portion above the first gate portion is smaller than the doping concentration of the impurity ions in the first gate portion and within a range of 1×10²⁰ to 1×10²¹ atoms/cm³, a doping concentration of the impurity ions in a third gate portion above the second gate portion is larger than the doping concentration of the impurity ions in the second gate portion within a range of 1×10²⁰ to 7.5×10²⁰ atoms/cm³, and a doping concentration of the impurity ions in a fourth gate portion in an uppermost portion is larger than doping concentration of the impurity ions in the lower portion within a range of 1×10²⁰ to 1×10²¹ atoms/cm³.

Preferably, the doping the second conductivity type impurity ions is implemented using a plasma doping method.

Preferably, the heat treatment is implemented using a rapid thermal process.

Preferably, the heat treatment is implemented under an oxygen atmosphere. In this case, a concentration of oxygen in the oxygen atmosphere preferably is less than 3000 ppm.

Alternatively, the heat treatment may be implemented under an ammonia (NH₃) atmosphere. In this case, a concentration of ammonia in the ammonia atmosphere preferably is less than 3000 ppm.

In yet another embodiment, a method of fabricating a dual gate comprises forming a gate insulation layer on a semiconductor substrate having a first region and a second region; forming a gate conductive layer on the gate insulation layer, the gate conductive layer comprising an upper portion overlying a lower portion; doping first conductivity type impurity ions in the gate conductive layer over the first and second regions, wherein the doping is performed with a concentration gradient so that a doping concentration in the upper portion of the gate conductive layer is higher than that in the lower portion of the gate conductive layer; doping second conductivity type impurity ions in the gate conductive layer in the second region of the semiconductor substrate using a mask for opening the gate conductive layer in the second region; and diffusing the first conductivity type impurity ions and the second conductivity type impurity ions by performing heat treatment.

Preferably, the heat treatment is implemented under an oxygen or ammonia (NH₃) atmosphere.

In still another embodiment, a method of fabricating a dual gate comprises forming a gate insulation layer on a semiconductor substrate having a first region and a second region; forming a gate conductive layer on the gate insulation layer, the gate conductive layer comprising at least three portions being divided in a vertical direction of the gate conductive layer with an uppermost portion overlying a middle portion and the middle portion overlying a lowermost portion; doping first conductivity type impurity ions in the at least three portions of the gate conductive layer, wherein the at least three portions have different doping concentrations and the doping is performed with a concentration gradient so that a doping concentration in the uppermost portion is higher than that in the lowermost portion; doping second conductivity type impurity ions in the gate conductive layer in the second region of the semiconductor substrate using a mask for opening the gate conductive layer in the second region of the semiconductor substrate; and diffusing the first conductivity type impurity ions and the second conductivity type impurity ions by performing heat treatment.

Preferably, the heat treatment is implemented under an oxygen or ammonia (NH₃) atmosphere.

Embodiments of the invention have, as compared to the conventional method which requires the use of two masks, an advantage of reducing production cost since the additional doping of N-type impurity ions is removed in a dual gate doping process and it is thus possible to perform the dual gate doping with only one mask. Also, since a concentration in the lower portion of the polysilicon layer is relatively reduced upon the doping of the N-type impurity ions, it is possible to prevent deterioration of Poly Depletion Rate in N-type and P-type MOS transistor regions.

### BRIEF DESCRIPTION OF THE DRAWINGS

FIG. 1 is a graph showing comparison of concentration before and after performing an additional ion implantation of N-type impurity ions in a conventional dual gate doping method.

FIGS. 2 through 4 are sectional views illustrating a dual gate doping method and a method of forming a dual gate using the same in accordance with a first embodiment of the invention.

FIG. 5 is a graph showing concentration distribution of impurity ions in the dual gate doping method in accordance with a first embodiment of the invention.

FIG. 6 is a sectional view illustrating a dual gate doping method and a method of forming a dual gate using the same in accordance with a second embodiment of the invention.

FIGS. 7 and 8 are graphs showing a SIMS result in the dual gate doping method and a method of forming a dual gate using the same in accordance with a second embodiment of the invention.

FIGS. 9 and 10 are graphs showing results of measuring a PDR of a polysilicon layer doped by the dual gate doping method in accordance with a second embodiment of the invention.

FIG. 11 is a sectional view illustrating a dual gate doping method and a method of forming a dual gate using the same in accordance with a third embodiment of the invention.

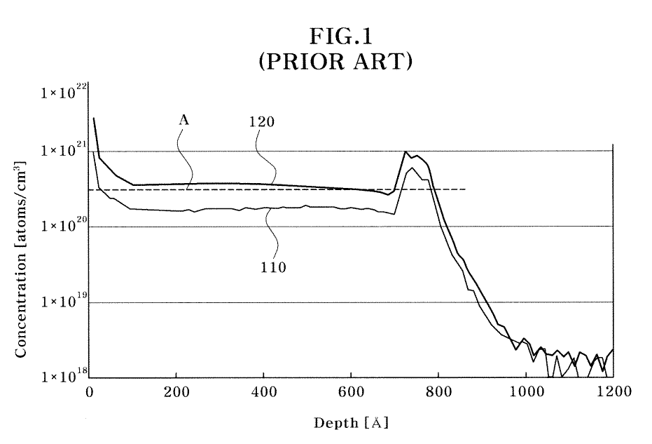

### DESCRIPTION OF SPECIFIC EMBODIMENTS

Hereinafter, a method for fabricating a photomask in accordance with the invention will be described in detail with reference to the accompanying drawings.

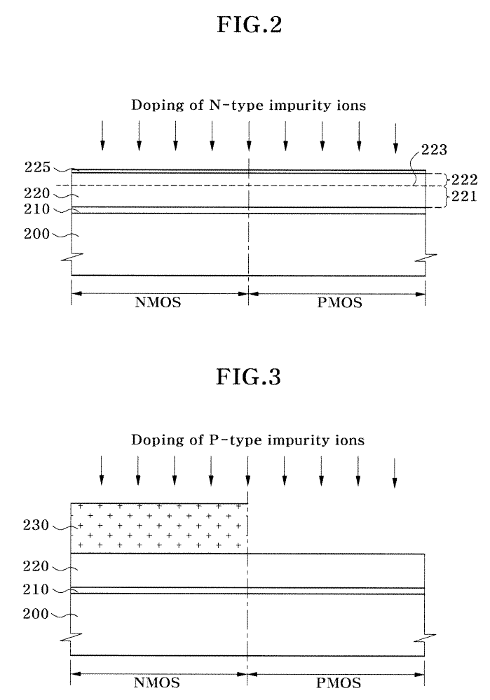

FIGS. 2 through 4 are sectional views illustrating a dual gate doping method and a method of forming a dual gate using the same in accordance with a first embodiment of the invention. Referring first to FIG. 2, a gate insulation layer 210 is formed on a semiconductor substrate 200 having a first region (NMOS) and a second region (PMOS). The first region (NMOS) is a region for disposing an N-type MOS transistor therein and the second region (PMOS) is a region for disposing a P-type MOS transistor therein. An oxide layer preferably is used as the gate insulation layer 210. A polysilicon layer 220 preferably is formed as a gate conductive layer on the gate insulation layer 210. The polysilicon layer preferably is formed using a conventional deposition method such as Chemical Vapor Deposition (CVD). Next, as shown by arrows, N-type impurity ions, e.g. phosphorus (P) ions are doped in the portions of the polysilicon layer corresponding to the first region (NMOS) and the second region (PMOS). This doping preferably is performed using a separate doping method after depositing an undoped (i.e., not doped with the impurity ions) polysilicon layer. Also, a method of depositing the polysilicon layer 220 with doping the phosphorus (P) ion upon the deposition of the polysilicon layer 220 preferably is used. In this case, the process preferably is performed by supplying a source gas of the phosphorus (P) ion together with a source gas for the deposition of the polysilicon layer. In any case, the polysilicon layer 220 has a profile in which the concentration of the phosphorus (P) ions within the polysilicon layer 220 is different by regions. Although the concentration of the phosphorus (P) ions varies by region, the mean doping concentration of the phosphorus (P) ions in the entire polysilicon layer 220 is about 100% of the final doping concentration. In this specification, the “final doping concentration” means a doping concentration allowing the normal operation as the N-type polygate.

More specifically, the phosphorus (P) ions preferably are doped in the polysilicon layer 220 with a low doping concentration in a lower portion 221 and a high doping concentration in an upper portion 222, the lower portion 221 and the upper portion 222 being divided along a direction perpendicular to a surface of the polysilicon layer 220. Here, the lower portion 221 extends from a portion adjacent to the gate insulation layer 210 to a boundary shown by a dotted line 223 along a vertical direction, and the upper portion 222 extends from the boundary to the upper surface of the polysilicon layer 220 along the vertical direction. In one example, the upper portion 222 is 5% to 40% of the entire thickness of the polysilicon layer 220 and the lower portion 221 is 60% to 95% of the entire thickness of the polysilicon layer 220.

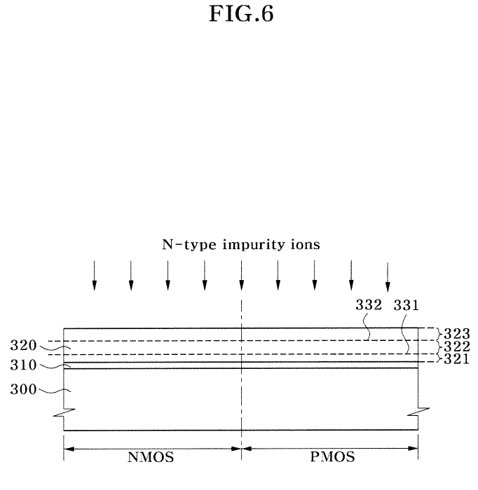

FIG. 5 is a graph showing distribution of doping concentration in the polysilicon layer 220 after doping the phosphorus (P) ions. As shown by a line 510 in FIG. 5, the doping concentration in the upper portion 222 of the polysilicon layer 220 is relatively high and the doping concentration in the lower portion 221 is relatively low. The doping concentration in the upper portion 222 of the polysilicon layer 220 is 140% to 180% of the final doping concentration (a dotted line indicated by “B”) and the doping concentration in the lower portion 221 of the polysilicon layer 220 is 20% to 60% of the final doping concentration (refer to “B”). The low doping concentration in the lower portion 221 facilitates the conductivity conversion in the lower portion of the P-type polygate in the subsequent process of doping P-type impurity ions to prevent the deterioration of the PDR in the second region (PMOS). And, the high doping concentration in the upper portion 222 allows sufficient supply of the phosphorus (P) ions in the lower portion of the N-type polygate through the subsequent diffusion process which is performed after the conductivity conversion of the P-type polygate.

In the case that the process of doping the impurity ions is separately performed after depositing the polysilicon layer 220, the doping of the phosphorus (P) ions preferably is divided into and performed in two steps, i.e. a doping process on the lower portion 221 and the doping process on the upper portion 222. The doping on the lower portion 221 preferably is performed with a relatively low implantation concentration at a relatively high implantation energy, and the doping on the upper portion 222 preferably is performed with a relatively high implantation concentration at a relatively low implantation energy. In the case that the doping of the impurity ions is performed at the same time upon the deposition of the polysilicon layer 220, a relatively small amount of the source gas of the phosphorus (P) ions is supplied during the deposition of the lower portion 221 of the polysilicon layer 220 and, on the contrary, a relatively large amount of the source gas of the phosphorus (P) ions is supplied during the deposition of the upper portion 222 of the polysilicon layer 220. In one example, the doping concentration of the phosphorus (P) ions in the lower portion 221 of the polysilicon layer 220 is 1×20²⁰ to 5×10²⁰ atoms/cm³. And, the doping concentration of the phosphorus (P) ions in the upper portion 222 of the polysilicon layer 220 is 1×10²⁰ to 1×10²¹ atoms/cm³, and yet higher than the doping concentration of the phosphorus (P) ions in the lower portion 221.

In the present embodiment, as the phosphorus (P) is doped in the upper portion of the polysilicon layer 220 with a high concentration, a defect can be generated in the upper surface of the polysilicon layer 220. Accordingly, an undoped polysilicon layer 225 can be formed to a thin thickness on the upper surface of the polysilicon layer 220. However, the aforementioned defect is not generated in every case, and thus the deposition of the undoped polysilicon layer 225 can be omitted at doping levels that do not generate the defect. Hereinafter, the deposition of the undoped polysilicon layer 225 will be omitted for simplicity of description.

Referring next to FIG. 3, a mask layer pattern 230 is formed on the polysilicon layer 220. In one example, the mask layer pattern 230 preferably is formed of a photoresist layer, but is not particularly limited thereto. If necessary, the mask layer pattern 230 can be formed of a hard mask layer. The mask layer pattern 230 is for selectively ion implanting on the second region (PMOS) and covers the first region (NMOS) but opens the second region (PMOS). Next, as shown by arrows, P-type impurity ions, e.g. boron (B) ions are doped. The doping of the P-type impurity ions preferably is performed using a conventional ion implantation method or using a Plasma Doping (PLAD) method. When using a conventional ion implantation method, the doping of the P-type impurity ions preferably is performed in an ion implantation apparatus, and when using a plasma doping method, the doping of the P-type impurity ions preferably is performed in a plasma doping chamber. By the doping of the P-type impurity ions, the conductivity of the portion of the polysilicon layer 220 in the second region (PMOS) is converted from the N-type to the P-type. As described with reference to FIG. 5, a mean doping concentration of the phosphorus (P) ions in the entire polysilicon layer 220 is high enough for the operation of the N-type polygate but the doping concentration of the phosphorus (P) ions in the lower portion 221 of the polysilicon layer 220 is lower than the mean doping concentration. Accordingly, the conductivity conversion by doping of the P-type impurity ions can be easily performed in the lower portion 221 of the polysilicon layer 220 in the second region (PMOS), and it is thus possible to the deterioration of the Poly Depletion Rate (PDR) in the second region (PMOS) or the P-type MOS transistor region. After doping the P-type impurity ions, the mask layer pattern 230 is removed.

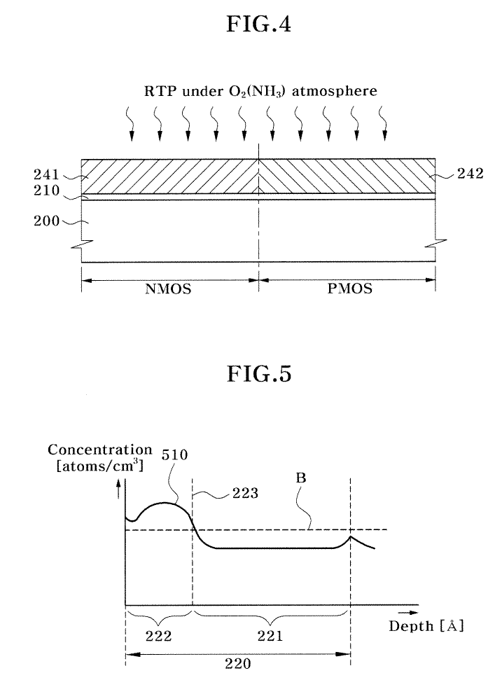

Referring next to FIG. 4, a heat treatment is performed to diffuse the doped impurity ions. This heat treatment preferably is performed in a Rapid Thermal Process. In one example, the heat treatment is performed under an oxygen (O₂) atmosphere. In another example, the heat treatment can be performed under an ammonia (NH₃) atmosphere. A concentration of the oxygen (O₂) or the ammonia (NH₃) preferably is less than about 3000 ppm in a rapid thermal processing chamber. The impurity ions doped by the thermal treatment is diffused in the polysilicon layer 220, generally from a high concentration to a low concentration, and impurity ions are thus diffused from the upper portion 222 of the polysilicon layer 220 to the lower portion 221. In this process, the oxygen (O₂) or the ammonia (NH₃) caps an impurity region in the upper portion 222 of the polysilicon layer 220 to maintain a high concentration over a predetermined level in the upper portion 222. As the result of this heat treatment, an N-type polygate layer 241 having an N-type conductivity is formed in the first region (NMOS) and a P-type polygate layer 242 having a P-type conductivity is formed in the second region (PMOS). Particularly, by performing the heat treatment under the oxygen (O₂) or ammonia (NH₃) atmosphere, the doping concentration of the N-type impurity ions, i.e. the phosphorus (P) ions in the polygate 241 is sufficiently high to perform the operation as an N-type gate and it is possible to the Poly Depletion Rate of the N-type polygate layer 241 to over a predetermined level. Further, an additional doping of the phosphorus (P) ions is not necessary and an additional mask requirement is thus removed.

FIG. 6 illustrates a dual gate doping method and a method of forming a dual gate using the same in accordance with a second embodiment of the invention. Referring to FIG. 6, a gate insulation layer 310 is formed on a semiconductor substrate 300 having a first region (NMOS) and a second region (PMOS). The first region (NMOS) is a region for disposing an N-type MOS transistor therein and the second region (PMOS) is a region for disposing a P-type MOS transistor therein. A polysilicon layer 320 is formed as a gate conductive layer on the gate insulation layer 310. Next, as indicated by arrows, N-type impurity ions, e.g. phosphorus (P) ions are doped in the polysilicon layer 320. This doping preferably is performed using a separate doping method after depositing the polysilicon layer not doped with the impurity ions. Alterntatively, a method of depositing the polysilicon layer 320 with doping the phosphorus (P) ion upon the deposition of the polysilicon layer 320 can be used. In this case, the process preferably is performed by supplying a source gas of the phosphorus (P) ion together with a source gas for the deposition of the polysilicon layer. In any case, the polysilicon layer 220 has a profile in which the concentration of the phosphorus (P) ions within the polysilicon layer 220 is different in each of a lower portion 321, a middle portion 322, and an upper portion 323, respectively. Although the concentration of the phosphorus (P) ions is different in the three regions, the mean doping concentration of the phosphorus (P) ions in the entire polysilicon layer 320 is a concentration allowing a normal operation as an N-type polygate, i.e. about 100% of the final doping concentration.

The doping concentration of the phosphorus (P) ions doped in the polysilicon layer 320 is shown to be different from each other in the lower portion 321, the middle portion 322, and the upper portion 323 of the polysilicon layer 320, which are divided by the first boundary portion 331 and the second boundary portion 332. Here, the lower portion 321 extends from a portion adjoining to the gate insulation layer 310 to the first a boundary 331, the middle portion 322 extends from the first boundary 331 to the second boundary 332, and the upper portion 324 extends from the second boundary 332 to the upper surface. In one example, the upper portion 323 is 5% to 30% of the total thickness of the polysilicon layer 320, the middle portion 322 is 40% to 85% of the total thickness of the polysilicon layer 320, and the lower portion 321 is 10% to 30% of the total thickness of the polysilicon layer 320.

The region in which the doping concentration of the phosphorus (P) ions is highest is the upper portion 323 of the polysilicon layer 320. The doping concentration of the phosphorus (P) ions in the upper portion 323 preferably is 140% to 160% of the final doping concentration. The region in which the doping concentration of the phosphorus (P) ions is lowest is the middle portion 322 of the polysilicon layer 322. The doping concentration of the phosphorus (P) ions in the middle portion 322 is 10% to 30% of the final doping concentration. The doping concentration of the phosphorus (P) ions in the lower portion 321 of the polysilicon layer 320 preferably is 10% to 30% of the final doping concentration, but is higher than the concentration of the phosphorus (P) ions in the middle portion 321. In one example, the doping concentration of the phosphorus (P) ions in the lower portion 321 is 1×10²⁰ to 5×10²⁰ atoms/cm³. The doping concentration of the phosphorus (P) ions in the middle portion 322 preferably is 1×10²⁰ to 133 10²¹ atoms/cm³, but is smaller than the doping concentration of the phosphorus (P) ions in the lower portion 321. And, the doping concentration of the phosphorus (P) ions in the upper portion 323 preferably is 1×10²⁰ to 1×10²¹ atoms/cm³, but is larger than the doping concentration of the phosphorus (P) ions in the lower portion 321.

After the N-type impurity ions, i.e. the phosphorus (P) ions are doped, the process as described with reference to FIGS. 3 and 4 is performed. That is to say, as described with reference to FIG. 3, the P-type impurity ions, e.g. boron (B) ions are doped in the portion of the polysilicon layer 320 corresponding to the second region (PMOS) using the mask layer pattern that opens the portion of the polysilicon layer 320 corresponding to the second region (PMOS). Next, as described with reference to FIG. 4, a rapid thermal process preferably is performed, preferably under an oxygen (O₂) or ammonia (NH₃) atmosphere, to diffuse the doped impurity ions.

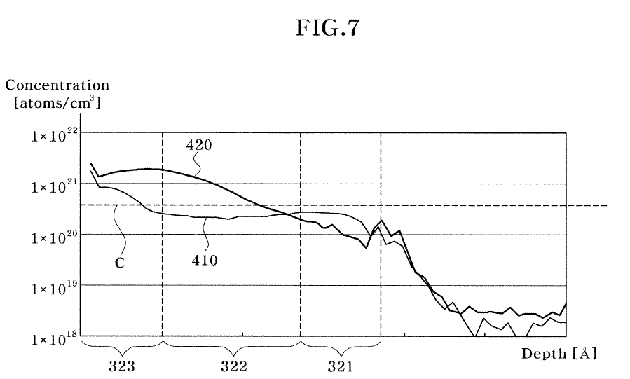

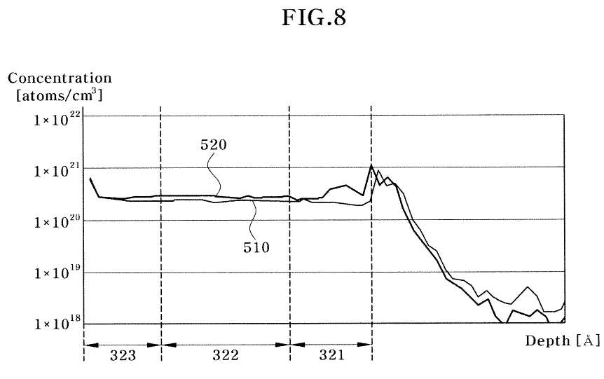

FIGS. 7 and 8 are graphs showing a Secondary Ion Mass Spectrometry (SIMS) result of the impurity ions in the dual gate doping method and a method of forming a dual gate using the same in accordance with a second embodiment of the invention. First, FIG. 7 is a graph showing the result of measuring the doping concentration by depth after doping the N-type impurity ions in a polysilicon layer (320 of FIG. 6) with a gradient by regions for 100% of the final doping concentration (refer to a dotted line “C”). As shown by a line “410” in FIG. 7, the doping concentration in the middle portion 322 of the polysilicon layer 320 is relatively lower than the doping concentration in the lower portion 321, but all of the doping concentrations are lower than the final doping concentration (refer to “C”) and the doping concentration in the upper portion 323 of the polysilicon layer 320 is shown highest. The line indicated by “420” in FIG. 7 illustrates the case of previously doping the N-type impurity ions with of 50% of the total concentration, implanting the P-type impurity ions and then additionally implanting the rest 50% using a conventional method. When comparing the two cases, it can be seen that the doping concentration in the middle portion 322 and the upper portion 323 of the polysilicon layer 320 is higher in the conventional case (refer to 420) than in the present embodiment (refer to 410) in the step after doping the N-type impurity ions and before doping of the P-type impurity ions and the heat treatment are performed. However, such difference is removed through the heat treatment process under the oxygen (O₂) or ammonia (NH₃) atmosphere.

FIG. 8 is a graph showing the result of measuring the doping concentration of the impurity ions by depth after performing the heat treatment. The line indicated by a reference numeral 510 in FIG. 8 shows distribution of a doping concentration of the N-type impurity ions after doping the N-type impurity ions and the P-type impurity ions by the dual gate doping concentration in accordance with the present embodiment and then performing the Rapid Thermal Process (RTP) under the oxygen (O₂) or ammonia (NH₃) atmosphere. And, the line indicated by a reference numeral “520” in FIG. 8 shows distribution of a doping concentration of the N-type impurity ions after previously doping the N-type impurity ions with of 50% of the total concentration, implanting the P-type impurity ions and then additionally implanting the rest 50% using a conventional method. When comparing the line shown by “510” and the line shown by “520”, they do not show a large difference. As described with reference to FIG. 7, although a difference between the doping concentrations of the N-type impurity ions in the present embodiment (refer to “410” of FIG. 7) and the conventional method (refer to “420” of FIG. 7) is large before performing the heat treatment, the difference between the doping concentrations of the N-type impurity ions is almost none after performing the heat treatment. The reason is as follows. In the conventional method, the N-type impurity ions of a high concentration present in the upper and middle portion of the polysilicon layer are mostly diffused to the low concentration region, i.e. the lower portion of the polysilicon layer. However, in the present embodiment, although the diffusion of the N-type impurity ions from the high concentration portion to the low concentration portion is generated in the same way, the oxygen (O₂) or ammonia (NH₃) caps the N-type impurity ions in the upper side of the polysilicon layer to maintain a concentration over a predetermined level in the upper portion of the polysilicon layer. Accordingly, although there is no additional process of doping the n-type impurity ions requiring the use of the additional mask as is in the present embodiment, the resulting doping concentration profile of the N-type impurity ions is actually the same as the case of additionally doping the N-type impurity ions.

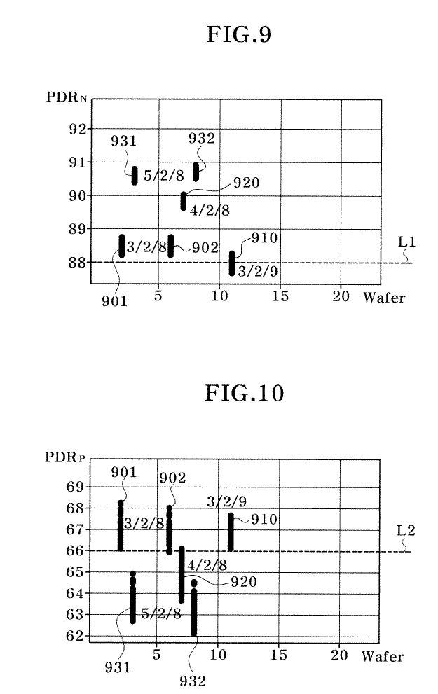

FIGS. 9 and 10 are graphs showing results of measuring a PDR of a polysilicon layer doped by the dual gate doping method in accordance with a second embodiment of the invention. Specifically, FIG. 9 is a graph showing the result of measuring the Poly Depletion Rate (PDR_{N}) of the portion of the polysilicon layer in the first region (NMOS), i.e. an N-type polysilicon layer, and FIG. 10 is a graph showing the result of measuring the Poly Depletion Rate (PDR_{P}) of the portion of the polysilicon layer in the second region (PMOS), i.e. an P-type polysilicon layer. In FIGS. 9 and 10, reference numerals indicate wafer samples and the accompanying numbers 3/2/8 show the doping concentrations of the N-type impurity ions in the lower portion, the middle portion and the upper portion of the polysilicon layer. That is to say, in the case of wafer samples 901, 902, the doping concentrations of the N-type impurity ions in the lower portion, the middle portion, and the upper portion are 3×10²⁰ atoms/cm³, 2×10²⁰ atoms/cm³ and 8×10²⁰ atoms/cm³, respectively. In the case of a wafer sample 910, the doping concentrations of the N-type impurity ions in the lower portion, the middle portion, and the upper portion are 3×10²⁰ atoms/cm³, 2×10²⁰ atoms/cm³ and 9×10²⁰ atoms/cm³, respectively. In the case of a wafer sample 920, the doping concentrations of the N-type impurity ions in the lower portion, the middle portion, and the upper portion are 4×10²⁰ atoms/cm³, 2×10²⁰ atoms/cm³ and 8×10²⁰ atoms/cm³, respectively. And, in the case of wafer samples 931, 932, the doping concentrations of the N-type impurity ions in the lower portion, the middle portion, and the upper portion are 5×10²⁰ atoms/cm³, 2×10²⁰ atoms/cm³ and 8×10²⁰ atoms/cm³, respectively.

First, it is desired that the Poly Depletion Rate (PDR_{N}) of the N-type polysilicon layer shown in FIG. 9 is measured to over 88% indicated by a doffed line L1. That is to say, on the basis of the dotted line L1, the PDR_{N} above the dotted line L1 means that it is free from the problem of the PDR_{N} of the N-type polysilicon layer. In this aspect, most wafer samples 901, 902, 920, 931, 932 are placed above the dotted line L1 and it can thus be appreciated that these wafer samples 901, 902, 920, 931, 932 show the PDR_{N} measurement results over a predetermined level. Next, it is desired that the Poly Depletion Rate (PDR_{P}) of the P-type polysilicon layer shown in FIG. 10 is measured to over 66% indicated by a dotted line L2. That is to say, on the basis of the dotted line L2, the PDR_{P} above the dotted line L2 means that it is free from the problem of the PDR_{P} of the P-type polysilicon layer. In this aspect, the wafer samples 901, 902, 910 are placed above the dotted line L2 and it can thus be appreciated that these wafer samples 901, 902, 910 show the PDR_{P} measurement results over a predetermined level. Consequently, when considering both the Poly Depletion Rate PDR_{N} of the N-type polysilicon layer and the Poly Depletion Rate PDR_{P} of the P-type polysilicon layer, it is desired that the doping concentrations of the N-type impurity ions in the lower portion, the middle portion, and the upper portion are 3×10²⁰ atoms/cm³, 2×10²⁰ atoms/cm³ and 8×10²⁰ atoms/cm³, respectively.

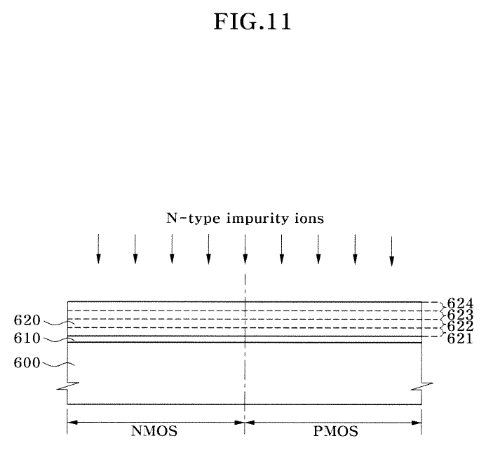

FIG. 11 is a sectional view illustrating a dual gate doping method and a method of forming a dual gate using the same in accordance with a third embodiment of the invention. Referring to FIG. 11, a gate insulation layer 610 is formed on a semiconductor substrate 600 having a first region (NMOS) and a second region (PMOS). The first region (NMOS) is a region for disposing an N-type MOS transistor therein and the second region (PMOS) is a region for disposing a P-type MOS transistor therein. A polysilicon layer 620 is formed as a gate conductive layer on the gate insulation layer 610. Next, as indicated by arrows, N-type impurity ions, e.g. phosphorus (P) ions are doped in the polysilicon layer 620. This doping can be performed using a separate doping method after deposit the polysilicon layer not doped with the impurity ions. Also, a method of depositing the polysilicon layer 620 with doping the phosphorus (P) ion upon the deposition of the polysilicon layer 620 can be used. In this case, it can be performed by supplying a source gas of the phosphorus (P) ion together with a source gas for the deposition of the polysilicon layer. In any case, the doping concentration of the phosphorus (P) ions is 100% of a concentration allowing the normal operation as an N-type polygate.

In the present embodiment, the doping concentration is different from each other in the four gate regions 621, 622, 623, 624 that are divided in a vertical direction. Specifically, the region in which the doping concentration of the phosphorus (P) ions is highest is the fourth gate region 624 placed in the uppermost portion of the polysilicon layer 620, and the region in which the doping concentration of the phosphorus (P) ions is lowest is the second gate region 622 of the polysilicon layer 620. The doping concentration of the phosphorus (P) ions in the first gate region 621 placed in the lowermost portion of the polysilicon layer 620 is higher than the doping concentration of the phosphorus (P) ions in the second gate region 622, but lower than the doping concentration of the phosphorus (P) ions in the fourth gate region 624. Also, the doping concentration of the phosphorus (P) ions in the third gate region 623 is higher than the doping concentration of the phosphorus (P) ions in the second gate region 622, but lower than the doping concentration of the phosphorus (P) ions in the fourth gate region 624. In one example, the doping concentration of impurity ions in the first gate region 621 in the lowermost portion is 1×10²⁰ to 5×10²⁰ atoms/cm³. The doping concentration of impurity ions in the second gate region 622 above the first gate region 621 is present in the range of 1×10²⁰ to 5×10²⁰ atoms/cm³ and is smaller than the doping concentration of impurity ions in the first gate region 621. The doping concentration of impurity ions in the third gate region 623 above the second gate region 622 is present in the range of 1×10²⁰ to 7.5×10²⁰ atoms/cm³ and is larger than the doping concentration of impurity ions in the second gate region 622. Further, the doping concentration of impurity ions in the fourth gate region 624 placed in the uppermost portion is present in the range of 1×10²⁰ to 7.5×10²¹ atoms/cm³ and is larger than the doping concentration of impurity ions in the third gate region 623.

After the N-type impurity ions, i.e. the phosphorus (P) ions are doped, the process as described with reference to FIGS. 3 and 4 is performed. That is to say, as described with reference to FIG. 3, the P-type impurity ions, e.g. boron (B) ions are doped in the portion of the polysilicon layer 620 corresponding to the second region (PMOS) using the mask layer pattern which opens the portion of the polysilicon layer 620 corresponding to the second region (PMOS). Next, as described with reference to FIG. 4, a rapid thermal process is performed under an oxygen (O₂) or ammonia (NH₃) atmosphere to diffuse the doped impurity ions.

While the invention has been described with respect to the specific embodiments, various changes and modifications may be made without departing from the spirit and scope of the invention as defined in the following claims.

What is claimed is:

1. A method of doping impurity ions in a dual gate, comprising:
doping first conductivity type impurity ions in a gate conductive layer over first and second regions of a semiconductor substrate, the gate conductive layer comprising an upper portion overlying a lower portion, wherein the doping is performed with a concentration gradient so that a doping concentration in the upper portion of the gate conductive layer is higher than the doping concentration in the lower portion;
doping second conductivity type impurity ions in the gate conductive layer in the second region of the semiconductor substrate using a mask for opening the gate conductive layer in the second region; and
diffusing the first conductivity type impurity ions and the second conductivity type impurity ions by performing heat treatment.

2. The method of claim 1, further comprising: after doping the first conductivity type impurity ions, forming an undoped polysilicon layer on the gate conductive layer.

3. The method of claim 1, comprising doping the first conductivity type impurity ions with a concentration of 100% of a final doping concentration.

4. The method of claim 1, wherein a doping concentration of the first conductivity type impurity ions in the lower portion of the gate conductive layer is 20% to 60% of a final doping concentration, and a doping concentration of the first conductivity type impurity ions in the upper portion of the gate conductive layer is 140% to 180% of a final doping concentration.

5. The method of claim 1, wherein a thickness of the lower portion of the gate conductive layer is 60% to 95% of a total thickness of the gate conductive layer and a thickness of the upper portion of the gate conductive layer is 5% to 40% of the total thickness of the gate conductive layer.

6. The method of claim 1, wherein the first region is an N-type MOS transistor region and the second region is a P-type MOS transistor region.

7. The method of claim 6, wherein the first conductivity type impurity ions are N-type impurity ions and the second conductivity type impurity ions are P-type impurity ions.

8. The method of claim 1, comprising forming the gate conductive layer by deposition and implementing doping the first conductivity type impurity ions in the gate conductive layer by supplying a source gas of the first conductivity type impurity ions upon deposition of the gate conductive layer.

9. The method of claim 8, comprising implementing the doping with the concentration gradient in which the doping concentration in the upper portion of the gate conductive layer is higher than that in the lower portion by variably controlling an amount of the supplied source gas of the first conductivity type impurity ions.

10. The method of claim 1, wherein the doping concentration of the impurity ions in the lower portion of the gate conductive layer is 1×10²⁰ to 5×10²⁰ atoms/cm³, and the doping concentration of the impurity ions in the upper portion of the gate conductive layer is larger than the doping concentration of the impurity ions in the lower portion of the gate conductive layer and within a range of 1×10²⁰ to 1×10²¹ atoms/cm³.

11. The method of claim 1, comprising implementing the doping of the second conductivity type impurity ions using a plasma doping method.

12. The method of claim 1, comprising implementing the heat treatment using a rapid thermal process.

13. The method of claim 11, comprising implementing the heat treatment under an oxygen atmosphere.

14. The method of claim 13, wherein a concentration of oxygen in the oxygen atmosphere is less than 3000 ppm.

15. The method of claim 1, comprising implementing the heat treatment under an ammonia (NH₃) atmosphere.

16. The method of claim 15, wherein a concentration of ammonia in the ammonia atmosphere is less than 3000 ppm.

17. A method of doping impurity ions in a dual gate, comprising:
doping first conductivity type impurity ions in at least three portions of a gate conductive layer over first and second regions of a semiconductor substrate, the at least three portions being divided in a vertical direction of the gate conductive layer, wherein the doping is performed with a concentration gradient so that a doping concentration in the uppermost portion of the gate conductive layer is higher than that in the lowermost portion of the gate conductive layer;
doping second conductivity type impurity ions in the gate conductive layer in the second region of the semiconductor substrate using a mask for opening the gate conductive layer in the second region; and
diffusing the first conductivity type impurity ions and the second conductivity type impurity ions by performing heat treatment.

18. The method of claim 17, further comprising, after doping the first conductivity type impurity ions, forming an undoped polysilicon layer on the gate conductive layer.

19. The method of claim 17, comprising doping the first conductivity type impurity ions with a concentration of 100% of a final doping concentration.

20. The method of claim 17, comprising forming the gate conductive layer by deposition and implementing doping the first conductivity type impurity ions in the gate conductive layer by supplying a source gas of the first conductivity type impurity ions upon deposition of the gate conductive layer.

21. The method of claim 20, comprising implementing the doping with the concentration gradient in which the doping concentration in the uppermost portion of the gate conductive layer is higher than that in the lowermost portion by variably controlling an amount of the supplied source gas of the first conductivity type impurity ions.

22. The method of claim 18, wherein the gate conductive layer is divided into three portions comprising a lower portion, a middle portion, and an upper portion in a vertical direction.

23. The method of claim 22, wherein a thickness of the lower portion is 10% to 30% of a total thickness of the gate conductive layer, a thickness of the middle portion is 40% to 85% of a total thickness of the gate conductive layer, and a thickness of the upper portion of the gate conductive layer is 5% to 30% of the total thickness of the gate conductive layer.

24. The method of claim 22, wherein a doping concentration of an N-type impurity ions in the lower portion is 10% to 30% of a final doping concentration, a doping concentration of the N-type impurity ions in the middle portion is 10% to 30% of a final doping concentration and smaller than the doping concentration of the N-type impurity ions in the lower portion, and a doping concentration of the N-type impurity ions impurity ions in the upper portion is 140% to 180% of a final doping concentration.

25. The method of claim 22, wherein a doping concentration of the impurity ions in the lower portion is 1×10²⁰ to 5×10²⁰ atoms/cm³, a doping concentration of the impurity ions in the middle portion is smaller than the doping concentration of the impurity ions in the lower portion and within a range of 1×10²⁰ to 1×10²¹ atoms/cm³, and a doping concentration of the impurity ions in the upper portion is larger than doping concentration of the impurity ions in the lower portion and within a range of 1×10²⁰ to 1×10²¹ atoms/cm³.

26. The method of claim 17, comprising implementing doping the first conductivity type impurity ions so that the gate conductive layer is divided into four portions in a vertical direction, a doping concentration of the impurity ions in a first gate portion in a lowermost portion is 1×10²⁰ to 5×10²⁰ atoms/cm³, a doping concentration of the impurity ions in a second gate portion above the first gate portion is smaller than the doping concentration of the impurity ions in the first gate portion and within a range of 1×10²⁰ to 1×10²¹ atoms/cm³, a doping concentration of the impurity ions in a third gate portion above the second gate portion is larger than the doping concentration of the impurity ions in the second gate portion and within a range of 1×10²⁰ to 7.5×10²⁰ atoms/cm³, and a doping concentration of the impurity ions in a fourth gate portion in an uppermost portion is larger than doping concentration of the impurity ions in the lower portion and within a range of 1×10²⁰ to 1×10²¹ atoms/cm³.

27. The method of claim 17, comprising implementing doping the second conductivity type impurity ions using a plasma doping method.

28. The method of claim 17, comprising implementing the heat treatment using a rapid thermal process.

29. The method of claim 17, comprising implementing the heat treatment under an oxygen atmosphere.

30. The method of claim 29, wherein a concentration of oxygen in the oxygen atmosphere is less than 3000 ppm.

31. The method of claim 17, comprising implementing the heat treatment under an ammonia (NH₃) atmosphere.

32. The method of claim 31, wherein a concentration of ammonia in the ammonia atmosphere is less than 3000 ppm.

33. A method of fabricating a dual gate, comprising:
forming a gate insulation layer on a semiconductor substrate having a first region and a second region;
forming a gate conductive layer on the gate insulation layer, the gate conductive layer comprising an upper portion overlying a lower portion;
doping first conductivity type impurity ions in the gate conductive layer over the first and second regions, wherein the doping is performed with a concentration gradient so that a doping concentration in the upper portion of the gate conductive layer is higher than that in the lower portion of the gate conductive layer;
doping second conductivity type impurity ions in the gate conductive layer in the second region of the semiconductor substrate using a mask for opening the gate conductive layer in the second region; and
diffusing the first conductivity type impurity ions and the second conductivity type impurity ions by performing heat treatment.

34. The method of claim 33, comprising implementing the heat treatment under an oxygen atmosphere or an ammonia (NH₃) atmosphere.

35. A method of fabricating a dual gate, comprising:
forming a gate insulation layer on a semiconductor substrate having a first region and a second region;
forming a gate conductive layer on the gate insulation layer, the gate conductive layer comprising at least three portions being divided in a vertical direction of the gate conductive layer with an uppermost portion overlying a middle portion and the middle portion overlying a lowermost portion;
doping first conductivity type impurity ions in the at least three portions of the gate conductive layer, wherein the at least three portions have different doping concentrations and the doping is performed with a concentration gradient so that a doping concentration in the uppermost portion is higher than that in the lowermost portion;
doping second conductivity type impurity ions in the gate conductive layer in the second region of the semiconductor substrate using a mask for opening the gate conductive layer in the second region of the semiconductor substrate; and
diffusing the first conductivity type impurity ions and the second conductivity type impurity ions by performing heat treatment.

36. The method of claim 35, comprising implementing the heat treatment under an oxygen atmosphere or an ammonia (NH₃) atmosphere.
